(19) United States
(12) Patent Application Publication
(10) Pub. No.: US 2021/0035782 A1
(43) Pub. Date: Feb. 4, 2021

(54) SUBSTRATE SUPPORTING DEVICE AND SUBSTRATE TREATING APPARATUS INCLUDING THE SAME

(71) Applicant: SEMES CO., LTD., Chungcheongnam-do (KR)

(72) Inventors: So Hyung Jiong, Daejeon (KR); Hyung Joon Kim, Gyeonggi-do (KR)

(21) Appl. No.: 16/924,513

(22) Filed: Jul. 9, 2020

(30) Foreign Application Priority Data
Jul. 29, 2019 (KR) 10-2019-0091906

(51) Int. Cl. H01J 37/32; H01L 21/3065; H01L 21/687

(52) U.S. Cl. CPC H01J 37/32642; H01J 37/32082; H01J 2237/334; H01L 21/3065; H01L 21/68735; H01J 37/32724

(57) ABSTRACT

Provided is an apparatus for a substrate supporting apparatus fixing a focus ring without using a clamp ring. The substrate supporting apparatus comprise a supporting plate for supporting a substrate; a side ring arranged to surround at least a part of a side surface of the supporting plate and including a first through hole; a focus ring arranged on the side ring and including a first circulation channel for circulation of a first temperature control fluid and a second through hole connecting the first circulation channel and a bottom surface therein; and a coupling bolt fixed to the focus ring penetrating through the first through hole and the second through hole from below the side ring and fixing the side ring and the focus ring to each other.

### BACKGROUND

### 1. Cross-Reference to Related Applications

This patent application claims the benefit of Korean Patent Application No. 10-2019-0091906, filed on Jul. 29, 2019, which is hereby incorporated by reference in its entirety into this application.

### 2. Field

The present invention relates to a substrate supporting device and a substrate treating apparatus including the same.

### 3. Description of the Related Art

When manufacturing a semiconductor device or a display device, various processes such as photography, etching, ashing, ion implantation, thin film deposition and cleaning are performed. Here, the etching process includes dry etching using plasma and wet etching using etchant. In particular, plasma is generated by very high temperature, strong electric field or radio frequency electromagnetic fields (RF Electromagnetic Fields), and refers to an ionized gas state comprising ions, electrons and radicals. The dry etching process is performed by particles contained in the plasma colliding with the substrate.

### SUMMARY

On the other hand, in the dry etching apparatus, the focus ring allows plasma to be generated limiting to around the substrate. Since the focus ring is located immediately adjacent to the substrate, it may affect the temperature of the substrate.

The conventional focus ring is fixed by a clamp ring. However, since the clamp ring takes up a lot of space in the process chamber, the clamp ring also serves as a limitation in designing the shape/size of the focus ring. This design limitation also affects the shape/position of the plasma formed around the substrate. Further, since the clamp ring is fastened to the edge of the focus ring, the central portion of the focus ring may be raised. Such raise of the central portion may cause poor adsorption of the substrate.

The problem to be solved by the present invention is to provide a substrate supporting apparatus capable of fixing a focus ring without using a clamp ring.

Another problem to be solved by the present invention is to provide a substrate treating apparatus employing the substrate supporting apparatus and performing dry etching using plasma.

The problems of the present invention are not limited to the problems mentioned above, and other problems not mentioned will be clearly understood by those skilled in the art from the following description.

One aspect of the substrate supporting apparatus of the present invention for achieving the above object comprises a supporting plate for supporting a substrate; a side ring arranged to surround at least a part of a side surface of the supporting plate and including a first through hole; a focus ring arranged on the side ring and including a first circulation channel for circulation of a first temperature control fluid and a second through hole connecting the first circulation channel and a bottom surface therein; and a coupling bolt fixed to the focus ring penetrating through the first through hole and the second through hole from below the side ring and fixing the side ring and the focus ring to each other.

Here, the coupling bolt comprises a head, a first part connected to the head and corresponding to the first through hole, a second part connected to the first part and corresponding to the second through hole, and a hollow formed to penetrate the head, the first part and the second part, and for transferring the first temperature control fluid.

Further, there is no screw thread inside the first through hole, a first screw thread is arranged inside the second through hole, a screw thread is not formed in the first part of the coupling bolt, and a second screw thread is formed in the second part of the coupling bolt and is coupled to the first screw thread of the second through hole.

A first temperature control fluid is supplied to the first circulation channel or the first temperature control fluid present in the first circulation channel is emitted through the hollow.

The side ring further comprises a second circulation channel for circulation of a second temperature control fluid.

The supporting plate further comprises a third circulation channel for circulation of a third temperature control fluid, wherein at least two of supply of the first temperature control fluid, supply of the second temperature control fluid and supply of the third temperature control fluid are controlled independently of each other.

Here, in a lower portion of the side ring, a first inlet and a first outlet of the first temperature control fluid are formed, a second inlet and a second outlet of the second temperature control fluid are formed, and the first inlet and the first outlet are arranged between the second inlet and the second outlet.

The coupling bolt comprises a coupling bolt coupling the side ring and the focus ring through the first inlet and a coupling bolt coupling the side ring and the focus ring through the second inlet.

A material of the coupling bolt is determined by process temperature, a thermal expansion coefficient of the focus ring and a material of the side ring.

One aspect of the substrate treating apparatus of the present invention for achieving the above another object comprises a process chamber; a substrate supporting device located in the process chamber to support a substrate; a gas supplying unit for supplying a process gas into the process chamber; and an antenna to excite the process gas by applying radio frequency power inside the process chamber, wherein the substrate supporting device comprises a supporting plate for supporting the substrate, a side ring arranged to surround at least a part of a side surface of the supporting plate and including a first through hole, a focus ring arranged on the side ring and including a first circulation channel for circulation of a first temperature control fluid and a second through hole connecting the first circulation channel and a bottom surface therein, and a coupling bolt fixed to the focus ring penetrating through the first through hole and the second through hole from below the side ring and fixing the side ring and the focus ring to each other.

Here, the coupling bolt includes a hollow therein, and the first temperature control fluid is transferred to the first circulation channel through the hollow.

Meanwhile, the side ring further includes a second circulation channel for circulation of a second temperature control fluid, the supporting plate further includes a third circulation channel for circulation of a third temperature control fluid, and at least two of supply of the first temperature control fluid, supply of the second temperature control fluid and supply of the third temperature control fluid are controlled independently of each other.

In a lower portion of the side ring, a first inlet and a first outlet of the first temperature control fluid are formed, a second inlet and a second outlet of the second temperature control fluid are formed, and the first inlet and the first outlet are arranged between the second inlet and the second outlet.

The coupling bolt comprises a coupling bolt coupling the side ring and the focus ring through the first inlet, and a coupling bolt coupling the side ring and the focus ring through the second inlet.

A material of the coupling bolt is determined by process temperature, a thermal expansion coefficient of the focus ring and a material of the side ring.

Other aspect of the substrate supporting apparatus of the present invention for achieving the above object comprises a supporting plate for supporting a substrate, a side ring arranged to surround at least a part of a side surface of the supporting plate and including a first through hole, a focus ring arranged on the side ring and including a first circulation channel for circulation of a first temperature control fluid and a second through hole connecting the first circulation channel and a bottom surface therein and a coupling bolt penetrating through the first through hole and the second through hole to fix the side ring and the focus ring to each other, wherein a head of the coupling bolt is jamming coupled to the side ring, a screw thread provided in the coupling bolt is screwed coupled to the focus ring, and a hollow provided in the coupling bolt is used for supplying a first temperature control fluid to the first circulation channel or as a path for emitting a first temperature control fluid present in the first circulation channel.

In a lower portion of the side ring, a first inlet and a first outlet of the first temperature control fluid are formed, the coupling bolt comprises a coupling bolt coupling the side ring and the focus ring through the first inlet and a coupling bolt coupling the side ring and the focus ring through the second inlet.

A material of the coupling bolt is determined by process temperature, a thermal expansion coefficient of the focus ring and a material of the side ring.

Details of other embodiments are included in the detailed description and drawings.

### BRIEF DESCRIPTION OF THE DRAWINGS

FIG. 1 is a cross-sectional view for describing a substrate supporting apparatus according to some embodiments of the present invention.

FIGS. 2 and 3 are diagrams for describing an exemplary shape of the first circulation channel of FIG. 1.

FIG. 4 is a side view of the fastening bolt of FIG. 1.

FIG. 5 is a plan view of the fastening bolt as viewed from the head side of the fastening bolt of FIG. 1.

FIG. 6 is an enlarged perspective view of area A of FIG. 1.

FIG. 7 is a cross-sectional view for describing a substrate treating apparatus according to some embodiments of the present invention.

### DETAILED DESCRIPTION

Hereinafter, preferred embodiments of the present invention will be described in detail with reference to the accompanying drawings. Advantages and features of the present invention, and methods for achieving them will be clarified with reference to embodiments described below in detail together with the accompanying drawings. However, the present invention is not limited to the embodiments disclosed below, but may be implemented in various different forms, and only the embodiments allow the publication of the present invention to be complete, and are provided to fully inform those skilled in the technical field to which the present invention pertains of the scope of the invention, and the invention is only defined by the scope of the claims. The same reference numerals refer to the same components throughout the specification.

When elements or layers are referred to as “on” or “above” of other elements or layers, it includes not only when directly above of the other elements or layers, but also other layer or other element intervened in the middle. On the other hand, when elements are referred to as “directly on” or “directly above,” it indicates that no other element or layer is intervened therebetween.

The spatially relative terms “below,” “beneath,” “lower,” “above,” “upper,” etc., as shown in figures, can be used to easily describe the correlation of an element or components with other elements or components, The spatially relative terms should be understood as terms including the different direction of the element in use or operation in addition to the direction shown in the drawing. For example, if the element shown in the figure is turned over, an element described as “below” or “beneath” the other element may be placed “above” the other element Accordingly, the exemplary term “below” can include both the directions of below and above. The element can also be oriented in other directions, so that spatially relative terms can be interpreted according to the orientation.

Although the first, second, etc. are used to describe various elements, components and/or sections, these elements, components and/or sections are not limited by these terms. These terms are only used to distinguish one element, component or section from another element, component or section. Therefore, the first element, first component or first section mentioned below may be a second element, second component or second section within the technical spirit of the present invention.

The terminology used herein is for describing the embodiments and is not intended to limit the present invention. In the present specification, the singular form also includes the plural form unless otherwise specified in the phrase. As used herein, “comprises” and/or “comprising” means that the components, steps, operations and/or elements mentioned above do not exclude the presence or additions of one or more other components, steps, operations and/or elements.

Unless otherwise defined, all terms (including technical and scientific terms) used in the present specification may be used as meanings commonly understood by those skilled in the art, to which the present invention pertains. In addition, terms defined in the commonly used dictionary are not ideally or excessively interpreted unless specifically defined.

Hereinafter, exemplary embodiments of the present invention will be described in detail with reference to the accompanying drawings, and in the description with reference to the accompanying drawings, the same or corresponding components are assigned the same reference numbers regardless of reference numerals, and the description overlapped therewith will be omitted.

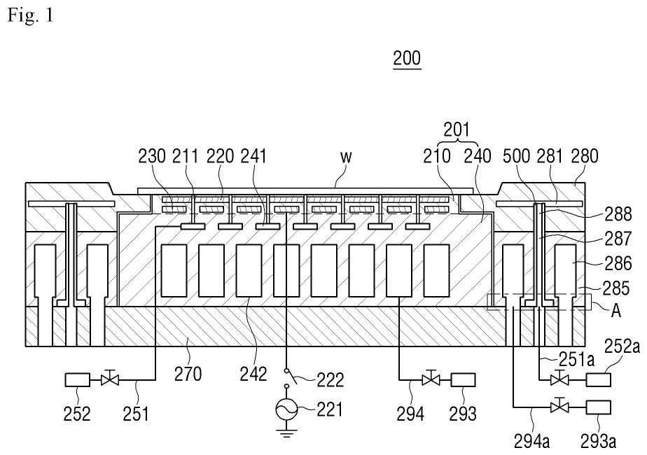

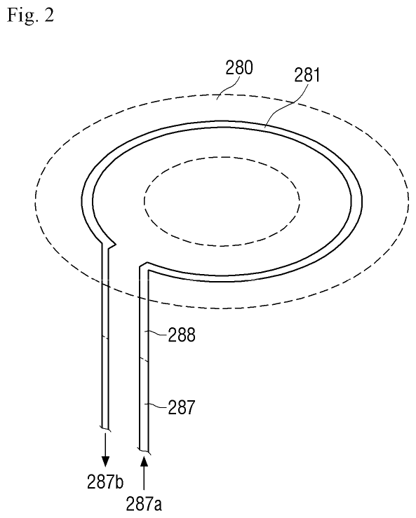

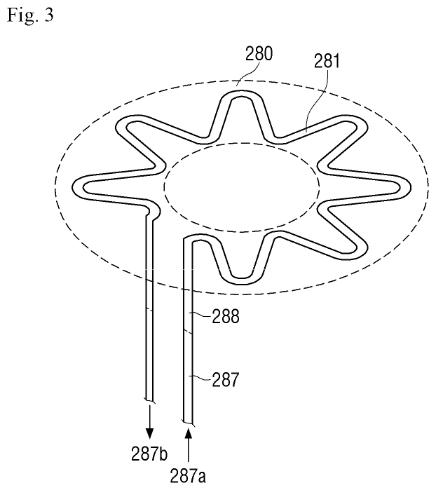

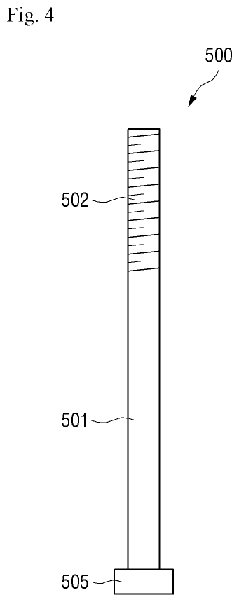

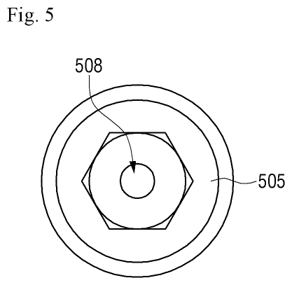

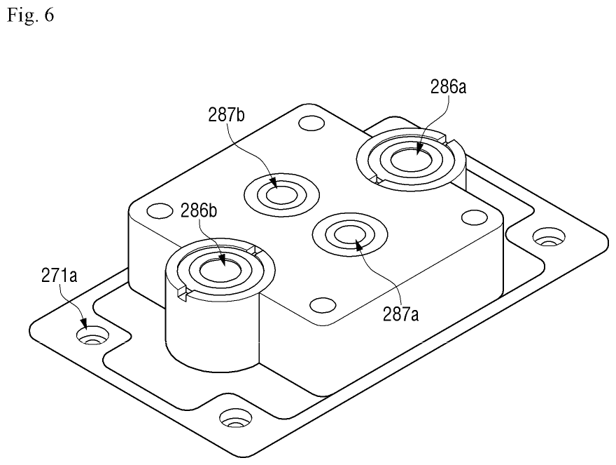

FIG. 1 is a cross-sectional view for describing a substrate supporting apparatus according to some embodiments of the present invention. FIGS. 2 and 3 are diagrams for describing an exemplary shape of the first circulation channel of FIG. 1. FIG. 4 is a side view of the fastening bolt of FIG. 1. FIG. 5 is a plan view of the fastening bolt as viewed from the head side of the fastening bolt of FIG. 1. FIG. 6 is an enlarged perspective view of area A of FIG. 1.

First, referring to FIG. 1, the substrate supporting apparatus 200 is an apparatus for supporting the substrate W, and for example, may be an electrostatic chuck that adsorbs and fixes the substrate W using electrostatic force.

The substrate supporting apparatus 200 includes a supporting plate 201, a side ring 285, a focus ring 280, a coupling bolt 500, an insulating plate 270, and the like.

First, the supporting plate 201 supports the substrate W. The supporting plate 201 includes a first plate 210 and a second plate 240 arranged in a lower portion of the first plate 210. The first plate 210 is provided as a disk-shaped dielectric substance, and the substrate W is located on the top surface of the first plate 210. As shown, the top surface of the first plate 210 has a smaller radius than the substrate W. Therefore, the edge region of the substrate W is located outside the first plate 210 and contacts with the focus ring 280.

The lower electrode 220 and the heater 230 are embedded in the first plate 210.

The lower electrode 220 is located in an upper portion of the heater 230. The lower electrode 220 is electrically connected to the first lower power supply 221. A switch 222 is installed between the lower electrode 220 and the first lower power supply 221. The lower electrode 220 may be electrically connected to the first lower power supply 221 by ON/OFF of the switch 222. When the switch 222 is turned on, a current is applied to the lower electrode 220. An electric force acts between the lower electrode 220 and the substrate W by the current applied to the lower electrode 220, and the substrate W is adsorbed to the first plate 210 by the electric force.

The heater 230 is electrically connected to an external power supply (not shown). The heater 230 generates heat by resisting a current applied from an external power supply. The generated heat is transferred to the substrate W through the first plate 210. The substrate W is maintained at a predetermined temperature by the heat generated from the heater 230. The heater 230 includes a spiral coil. The heater 230 may be embedded in the first plate 210 at uniform intervals.

The second plate 240 is located in a lower portion of the first plate 210.

The bottom surface of the first plate 210 and the top surface of the second plate 240 may be adhered by an adhesive. The second plate 240 may be made of aluminum.

A fourth circulation channel 241, a third circulation channel 242, and the like are formed on the second plate 240.

The fourth circulation channel 241 is provided as a passage through which the heat transfer medium circulates. The fourth circulation channel 241 may be formed in a spiral shape inside the second plate 240. Alternatively, the fourth circulation channel 241 may be arranged such that ring-shaped channels having different radiuses have the same center. Each of the fourth circulation channels 241 may communicate with each other. The fourth circulation channels 241 may be formed at the same height, but are not limited thereto.

The fourth circulation channel 241 is connected to the heat transfer medium storage unit 252 through a supply line 251. The heat transfer medium storage unit 252 stores heat transfer medium. The heat transfer medium may include an inert gas. According to an embodiment, the heat transfer medium includes helium (He) gas. The helium gas is supplied to the fourth circulation channel 241 through the supply line 251, and is supplied to the bottom surface of the substrate W sequentially passing through the supply channel 211. The supply channel 211 extends upward from the fourth circulation channel 241 and is provided to a top surface of the second plate 240. The helium gas serves as a medium through which heat transferred from the plasma to the substrate W is transferred to the substrate supporting apparatus 200.

The ion particles contained in the plasma are attracted by the electric force formed in the substrate supporting apparatus 200 and moved to the substrate supporting apparatus 200, and collide with the substrate W in the process of moving to perform an etching process. In the process of the ion particles colliding with the substrate W, heat is generated in the substrate W. The heat generated from the substrate W is transferred to the substrate supporting apparatus 200 through helium gas supplied to the space between the bottom surface of the substrate W and the top surface of the first plate 210. Thereby, the substrate \V can be maintained at a set temperature.

The third circulation channel 242 is provided as a passage through which the third temperature control fluid circulates. The third circulation channel 242 may be formed in a spiral shape inside the second plate 240. Alternatively, the third circulation channel 242 may be arranged such that ring-shaped channels having different radiuses have the same center. Each of the third circulation channels 242 may communicate with each other. The third circulation channel 242 may have a larger cross-sectional area than the fourth circulation channel 241. The third circulation channels 242 may be formed at the same height, but are not limited thereto. The third circulation channel 242 may be positioned in a lower portion of the fourth circulation channel 241.

The side ring 285 is arranged to surround at least a part of the side surface of the supporting plate 201 (i.e., the second plate 240).

A second circulation channel 286 is formed in the side ring 285 for circulation of a second temperature control fluid (e.g., cooling water). The second circulation channel 286 may be arranged such that ring-shaped channels having different radiuses have the same center. Each of the second circulation channels 286 may communicate with each other. The second circulation channels 286 may be formed at the same height, but are not limited thereto. The second circulation channel 286 may be located in a. lower portion of the first circulation channel 281.

The second circulation channel 286 is connected to the fluid storage unit 293a through the fluid supply line 294a. in the fluid storage unit 293a, a temperature control fluid such as cooling water is stored. The second temperature control fluid is transferred to the second circulation channel 286 through the fluid supply line 294a.

Further, the side ring 285 includes a first through hole 287. As described later, the first through hole 287 is connected to the second through hole 288 of the focus ring 280.

The focus ring 280 is arranged in the edge region of the substrate supporting apparatus 200. The focus ring 200 has a ring shape and is arranged along the circumference of the first plate 210. The top surface of the focus ring 280 may be stepped so that the outer portion (i.e., the portion not contacting the substrate W) is higher than the inner portion (i.e., the portion contacting the substrate W). The inner surface of the top surface of the focus ring 280 is located at the same height as the top surface of the first plate 210. The inner side of the top surface of the focus ring 280 supports the edge region of the substrate W located outside the first plate 210. The outer portion of the focus ring 280 is provided to surround the edge region of the substrate W. The focus ring 280 expands the electric field forming region so that the substrate W is located at the center of the region where the plasma is formed. Thereby, the plasma is uniformly formed over the entire area of the substrate W so that each area of the substrate W can be etched uniformly.

The focus ring 280 may be formed of SiC, Si, or the like, to withstand high process temperatures.

The temperature of the focus ring 280 may be increased by heat generated during the process gas excitation process and when the ion particles contained in the plasma are attracted by the electric force of the substrate supporting apparatus 200 and collide with the substrate supporting apparatus 200.

In order to adjust the temperature of the focus ring 280, a first circulation channel 281 for circulation of a first temperature control fluid (e.g., an inert gas) and a second through hole 288 connecting a first circulation channel 281 and the bottom surface of the focus ring 280 are included inside the focus ring 280. The inert gas may be, for example, helium gas.

The first circulation channel 281 is connected to the fluid storage unit 252a through the fluid supply line 251a. The fluid storage unit 252a stores a temperature control fluid such as an inert gas (e.g., helium gas).

The first circulation channel 281 may be substantially circular shape inside the focus ring 280, as illustrated in FIG. 2. Or, as shown in FIG. 3, it may be a zigzag or wavy shape. Alternatively, the first circulation channel 281 may be formed in a spiral shape inside the focus ring 280, Alternatively, the first circulation channel 281 may be arranged such that ring-shaped channels having different radiuses have the same center. Each of the first circulation channels 281 may communicate with each other. The first circulation channel 281 may be formed at the same height. The first circulation channel 281 may be located above the second circulation channel 286.

Also, the second through hole 288 is connected to the first through hole 287 of the side ring 285.

Meanwhile, the side ring 285 and the focus ring 280 are fixed to each other by a coupling bolt 500. The coupling bolt 500 penetrates the first through hole 287 and the second through hole 288 from below the side ring 285. That is, the focus ring 280 may be fixed/installed by the coupling bolt 500 without installing a separate clamp ring.

The coupling bolt 500 may be made of a ceramic, metal or resin in consideration of the high process temperature, the thermal expansion coefficient of the material of the focus ring 280 (for example, SiC, Si), and the material of the side ring 285.

Here, referring to FIGS. 4 and 5, the coupling bolt 500 may include a head 505, a first part 501, a second part 503 and a hollow 508, The first part 501 is a part connected to the head 505 and corresponding to the first through hole 287. The second part 502 is a part connected to the first part 501 and corresponding to the second through hole 288.

Meanwhile, there is no screw thread inside the first through hole 287 of the side ring 285, and no screw thread is formed in the first part 501 of the coupling bolt 500.

On the other hand, a first screw thread is arranged inside the second through hole 288 of the focus ring 280, and a second screw thread is formed in the second part 502 of the coupling bolt 500, The first screw thread of the second through hole 288 and the second screw thread of the coupling bolt 500 are coupled to each other. Specifically, since there is no screw thread inside the first through hole 287 of the side ring 285, the coupling bolt 500 can penetrate the first through hole 287 without screwed coupling. The coupling bolt 500 penetrates the side ring 285 and is coupled to the focus ring 280, thereby coupling the side ring 285 and the focus ring 280 to each other. By having such a structure, it is possible to facilitate the manufacturing and/or maintenance process.

In particular, as shown, the coupling bolt 500 couples the side ring 285 and the middle part of the focus ring 280 to each other.

For example, referring to FIG. 6, the first inlet 287a and the first outlet 287b of the first temperature control fluid are formed, and the second inlet 286a and the second outlet 286b of the second temperature control fluid are formed in the lower portion of the side ring 285 (i.e., portion A of FIG. 1). As illustrated, between the second inlet 286a and the second outlet 286b, a first inlet 287a and a first outlet 287b may be arranged. That is, the first inlet 287a and the first outlet 287b may be arranged at the central portion of the side ring 285. In the example of FIG. 6, when the side ring 285 and the focus ring 280 are coupled, the coupling bolt 500 installed through the first inlet 287a and the coupling provided installed through the first outlet 287b are required. A bolt is fastened to the fastening hole 271a of FIG. 6 to fix the insulating plate 270 and the side ring 285 to each other.

In the substrate supporting apparatus 200 according to some embodiments of the present invention, since the focus ring 280 is not fixed using the clamp ring, the size of the substrate supporting apparatus 200 may be reduced, and without limitation of the clamp ring, the shape/size of the focus ring 280 may be designed.

In addition, when the conventional focus ring is fixed by the clamp ring, the central portion of the focus ring could be raised (i.e., a lifting phenomenon) because the clamp ring is fastened to the edge of the focus ring. However, in the substrate supporting apparatus 200 according to some embodiments of the present invention, the coupling bolt 500 is fastened to the middle portion of the focus ring 280 to fix the focus ring 280 (see FIGS. 1 and 6), and thus the above-mentioned lifting phenomenon does not occur. Therefore, the substrate supporting apparatus 200 can stably support the substrate W.

In addition, the hollow 508 is formed to penetrate the head 505, the first part 501, the second part 502. The first temperature control fluid is transferred to the first circulation channel 281 through the hollow 508. The first temperature control fluid stored in the fluid storage unit 252a is transferred through a fluid supply line 251a, a first through hole 287, and a second through hole 288 (that is, the hollow 508 of the coupling bolt 500) to the first circulation channel 281. That is, without forming a separate supply line for transferring the first temperature control fluid to the first circulation channel 281, the hollow 508 is formed in the coupling bolt 500 to supply the first temperature control fluid through the hollow 508.

In summary, the first through hole 287, the second through hole 288, and the coupling bolt 500 are used for the coupling of the side ring 285 and the focus ring 280, and used for supplying the first temperature control fluid as well.

The temperature of the focus ring 280 may be decreased by the first temperature control fluid circulating through the first circulation channel 281. The radicals in the plasma have the property of striking a higher temperature object. By decreasing the temperature of the focus ring 280 using the first temperature control fluid, radicals may be further striking the substrate W rather than the focus ring 280. Therefore, it is possible to maximize the process efficiency.

Further, the focus ring 280 includes a first circulation channel 281 for circulation of the first temperature control fluid. The side ring 285 includes a second circulation channel 286 for circulation of the second temperature control fluid. The supporting plate 201 includes a third circulation channel 242 for circulation of the third temperature control fluid. Here, at least two of the supply of the first temperature control fluid, the supply of the second temperature control fluid, and the supply of the third temperature control fluid may be controlled independently of each other, That is, by individually adjusting the flow rate, speed, temperature, etc. of each temperature control fluid, the temperature of each part of the substrate supporting apparatus (i.e., supporting plate 201, focus ring 280, etc.) can be optimized for the process.

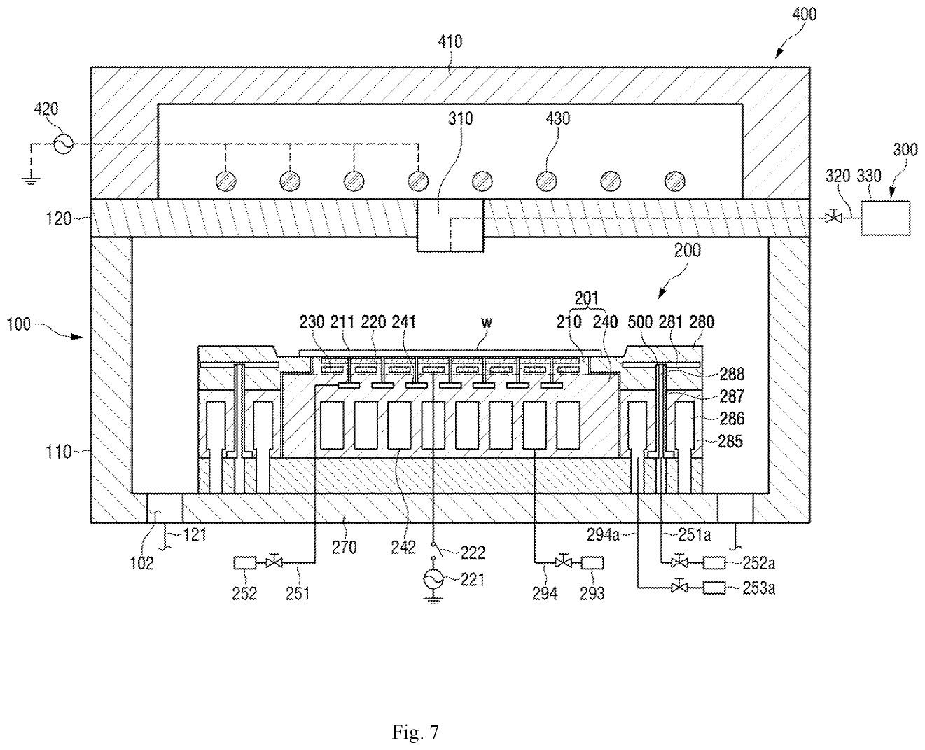

FIG. 7 is a cross-sectional view for describing a substrate treating apparatus according to some embodiments of the present invention. In FIG. 7, the dry etching device is exemplarily described, but is not limited thereto. For convenience of description, what has been described with reference to FIGS. 1 to 6 is omitted.

Referring to FIG. 7, a substrate treating apparatus according to some embodiments of the present invention includes a process chamber 100, a substrate supporting apparatus 200, a gas supplying unit 300, and a plasma generating unit 400.

The process chamber 100 provides a space in which the substrate W treating process is performed. The process chamber 100 includes a body 110, a sealing cover 120, and the like.

In the body 110, a space with an open top surface is formed therein. The inner space of the body 110 is provided as a space in which the substrate W treating process is performed. The body 110 is made of a metal material. The body 110 may be made of aluminum. An exhaust hole 102 is formed on the bottom surface of the body 110. The exhaust hole 102 is connected to the exhaust line 121. Reaction by-products generated in the process and gas staying in the interior space of the body may be emitted to the outside through the exhaust line 121. The inside of the body 110 is depressurized to a predetermined pressure by the exhaust process.

The sealing cover 120 covers the open top surface of the body 110. The sealing cover 120 is provided with a plate shape, and seals the inner space of the body 110. The sealing cover 120 may be made of a material different from the body 110. The sealing cover 120 may be provided as a dielectric substance.

The substrate supporting apparatus 200 is located inside the body 110. The substrate supporting apparatus 200 supports the substrate W. The substrate supporting apparatus 200 includes an electrostatic chuck that adsorbs the substrate W using electrostatic force.

As described with reference to FIGS. 1 to 6, the substrate supporting apparatus 200 includes a supporting plate 201, a side ring 285, a focus ring 280 and a coupling bolt 500. The supporting plate 201 supports the substrate. The side ring 285 is arranged to surround at least a part of the side surface of the supporting plate 201, and includes a first through hole 287. The focus ring 280 is arranged on the side ring 285, and includes a first circulation channel 281 for circulation of the first temperature control fluid, and a second through hole 288 connecting the first circulation channel 281 and the bottom surface therein. The coupling bolt 500 is fixed to the focus ring 280 penetrating through the first through hole 287 and the second through hole 288 from below the side ring 285 and fixing the side ring 285 and the focus ring 280 to each other.

The coupling bolt 500 includes a hollow therein (see 508 in FIG. 5) and the first temperature control fluid passes through the hollow 508 and is transferred to the first circulation channel.

The side ring 285 includes a second circulation channel 286 for circulation of the second temperature control fluid. The supporting plate 201 includes a third circulation channel 242 for circulation of the third temperature control fluid. Here, at least two of the supply of the first temperature control fluid, the supply of the second temperature control fluid, and the supply of the third temperature control fluid may be controlled independently of each other.

The gas supplying unit 300 supplies process gas inside the process chamber 100. The gas supplying unit 300 includes a gas supplying nozzle 310, a gas supplying line 320, and a gas storage unit 330. The gas supplying nozzle 310 may be installed at the central portion of the sealing cover 120. A spraying port is formed on the bottom surface of the gas supplying nozzle 310. The spraying port is located in a lower portion of the sealing cover 120 and supplies process gas into the process chamber 100. The gas supplying line 320 connects the gas supplying nozzle 310 and the gas storage unit 330. The gas supplying line 320 supplies the process gas stored in the gas storage unit 330 to the gas supplying nozzle 310. A valve is installed in the gas supplying line 320. The valve opens and closes the gas supplying line 320 and controls the flow rate of the process gas supplied through the gas supplying line 320.

The plasma generating unit 400 excites the process gas supplied inside the process chamber 100 by applying radio frequency power inside the process chamber 100. The plasma generating unit 400 includes a housing 410, an upper power supply 420, and an antenna unit 430.

The bottom surface of the housing 410 is opened, and a space is formed therein. The housing 410 is located on the upper portion of the sealing cover 120 and is placed on the top surface of the sealing cover 120. The inside of the housing 410 is provided as a space where the antenna 430 is located. The upper power supply 420 generates a radio frequency current. The generated radio frequency current is applied to the antenna 430. The antenna 430 applies radio frequency power inside the process chamber 100. The antenna 430 may be arranged such that ring shaped coils having different radiuses are located at the same center. The radio frequency power applied from the antenna 430 excites the process gas staying inside the process chamber 100. The excited process gas is provided to the substrate W to treat the substrate W. The excitation process gas may perform an etching process.

Although the embodiments of the present invention have been described with reference to the above and the accompanying drawings, those of ordinary skill in the art to which the present invention pertains could understand that the present invention may be implemented in other specific forms without changing its technical spirit or essential features. Therefore, it should be understood that the embodiments described above are illustrative in all respects and not restrictive.

What is claimed is:

1. A substrate supporting apparatus comprising:
a supporting plate for supporting a substrate;
a side ring arranged to surround at least a part of a side surface of the supporting plate and including a first through hole;
a focus ring arranged on the side ring and including a first circulation channel for circulation of a first temperature control fluid and a second through hole connecting the first circulation channel and a bottom surface therein; and
a coupling bolt fixed to the focus ring penetrating through the first through hole and the second through hole from below the side ring and fixing the side ring and the focus ring to each other.

2. The substrate supporting apparatus of claim 1,
wherein the coupling bolt comprises,
a head,
a first part connected to the head and corresponding to the first through hole,
a second part connected to the first part and corresponding to the second through hole, and
a hollow formed to penetrate the head, the first part and the second part, and for transferring the first temperature control fluid.

3. The substrate supporting apparatus of claim 2,
wherein there is no screw thread inside the first through hole,
wherein a first screw thread is arranged inside the second through hole,
wherein a screw thread is not formed in the first part of the coupling bolt,
wherein a second screw thread is formed in the second part of the coupling bolt, and is coupled to the first screw thread of the second through hole.

4. The substrate supporting apparatus of claim 2,
wherein a first temperature control fluid is supplied to the first circulation channel or the first temperature control fluid present in the first circulation channel is emitted through the hollow.

5. The substrate supporting apparatus of claim 1,
wherein the side ring further comprises a second circulation channel for circulation of a second temperature control fluid.

6. The substrate supporting apparatus of claim 5,
wherein the supporting plate further comprises a third circulation channel for circulation of a third temperature control fluid,
wherein at least two of supply of the first temperature control fluid, supply of the second temperature control fluid and supply of the third temperature control fluid are controlled independently of each other.

7. The substrate supporting apparatus of claim 5,
wherein in a lower portion of the side ring,
a first inlet and a first outlet of the first temperature control fluid are formed,
a second inlet and a second outlet of the second temperature control fluid are formed, and
the first inlet and the first outlet are arranged between the second inlet and the second outlet.

8. The substrate supporting apparatus of claim 7,
wherein the coupling bolt comprises,
a coupling bolt coupling the side ring and the focus ring through the first inlet, and
a coupling bolt coupling the side ring and the focus ring through the second inlet.

9. The substrate supporting apparatus of claim 1,
wherein a material of the coupling bolt is determined by process temperature, a thermal expansion coefficient of the focus ring and a material of the side ring.

10. A substrate treating apparatus comprising:
a process chamber;
a substrate supporting apparatus located in the process chamber to support a substrate;
a gas supplying unit for supplying a process gas into the process chamber; and
an antenna to excite the process gas by applying radio frequency power inside the process chamber,
wherein the substrate supporting apparatus comprises,
a supporting plate for supporting the substrate,
a side ring arranged to surround at least a part of a side surface of the supporting plate and including a first through hole,
a focus ring arranged on the side ring and including a first circulation channel for circulation of a first temperature control fluid and a second through hole connecting the first circulation channel and a bottom surface therein, and
a coupling bolt fixed to the focus ring penetrating through the first through hole and the second through hole from below the side ring and fixing the side ring and the focus ring to each other.

11. The substrate treating apparatus of claim 10,
wherein the coupling bolt includes a hollow therein, and the first temperature control fluid is transferred to the first circulation channel through the hollow.

12. The substrate treating apparatus of claim 10,
wherein the side ring further includes a second circulation channel for circulation of a second temperature control fluid,
wherein the supporting plate further includes a third circulation channel for circulation of a third temperature control fluid,
wherein at least two of supply of the first temperature control fluid, supply of the second temperature control fluid and supply of the third temperature control fluid are controlled independently of each other.

13. The substrate treating apparatus of claim 12,
wherein in the lower portion of the side ring,
a first inlet and a first outlet of the first temperature control fluid are formed,
a second inlet and a second outlet of the second temperature control fluid are formed, and
the first inlet and the first outlet are arranged between the second inlet and the second outlet.

14. The substrate treating apparatus of claim 13,
wherein the coupling bolt comprises,
a coupling bolt coupling the side ring and the focus ring through the first inlet, and
a coupling bolt coupling the side ring and the focus ring through the second inlet.

15. The substrate treating apparatus of claim 10,
wherein a material of the coupling bolt is determined by process temperature, a thermal expansion coefficient of the focus ring and a material of the side ring.

16. A substrate supporting apparatus comprising:
a supporting plate for supporting a substrate;
a side ring arranged to surround at least a part of a side surface of the supporting plate and including a first through hole;
a focus ring arranged on the side ring and including a first circulation channel for circulation of a first temperature control fluid and a second through hole connecting the first circulation channel and a bottom surface therein; and
a coupling bolt penetrating through the first through hole and the second through hole to fix the side ring and the focus ring to each other,
wherein a head of the coupling bolt is jamming coupled to the side ring, a screw thread provided in the coupling bolt is screwed coupled to the focus ring, and a hollow provided in the coupling bolt is used for supplying a first temperature control fluid to the first circulation channel or as a path for emitting a first temperature control fluid present in the first circulation channel.

17. The substrate supporting apparatus of claim 16,
where in a lower portion of the side ring,
a first inlet and a first outlet of the first temperature control fluid are formed,
wherein the coupling bolt comprises,
a coupling bolt coupling the side ring and the focus ring through the first inlet, and
a coupling bolt coupling the side ring and the focus ring through the second inlet.

18. The substrate supporting apparatus of claim 16,
wherein a material of the coupling bolt is determined by process temperature, a thermal expansion coefficient of the focus ring and a material of the side ring.
